(19) United States
(12) Patent Application Publication
(10) Pub. No.: US 2025/0072302 A1
(43) Pub. Date: Feb. 27, 2025

(54) ASSEMBLY COMPRISING AT LEAST TWO NON-VOLATILE RESISTIVE MEMORIES AND TWO SELECTORS, ARRAY AND MANUFACTURING METHOD ASSOCIATED THEREWITH

(71) Applicants: COMMISSARIAT A L'ENERGIE ATOMIQUE ET AUX ENERGIES ALTERNATIVES, PARIS (FR); WEEBIT NANO LTD, HOD HASHARON (IL)

(72) Inventors: Jean-Baptiste DORY, GRENOBLE CEDEX 09 (FR); Gabriel MOLAS, GRENOBLE CEDEX 09 (FR); Jean-François NODIN, GRENOBLE CEDEX 09 (FR); Anthonin VERDY, GRENOBLE CEDEX 09 (FR)

(21) Appl. No.: 18/721,012

(22) PCT Filed: Dec. 22, 2022
(86) PCT No.: PCT/EP2022/087644

§ 371 Date: Jun. 17, 2024

(30) Foreign Application Priority Data
Dec. 23, 2021 (FR) 2114409

(51) Int. Cl. H10N 70/20; H10B 63/00; H10N 70/00

(52) U.S. Cl. CPC H10N 70/24; H10B 63/24; H10B 63/845; H10N 70/063; H10N 70/823; H10N 70/8833

(57) ABSTRACT

An assembly includes at least two non-volatile resistive memories arranged electrically in parallel to one another and each being electrically connected in series to a selector layer respectively forming at least two selectors, each one assigned to one of the memories, the assembly including two upper electrodes which both extend over the selector layer and which are electrically insulated from each other, one of the resistive memories extending against a lateral surface of the first upper electrode and another of the resistive memories extending against a lateral surface of the second upper electrode.

### TECHNICAL FIELD OF THE INVENTION

The technical field of the invention is that of non-volatile resistive memories. It also relates to the manufacture of such memories.

### TECHNOLOGICAL BACKGROUND OF THE INVENTION

The invention is part of the development of so-called “crossbar” memory arrays, in which a plurality of memory points are each located at the intersection between a conductive row and a conductive column. Each memory point is then addressed, for example by applying a voltage between the conductive row and the conductive column to which it is connected.

The invention more particularly relates to memory points comprising a resistive memory, i.e. a memory in which information is stored in the form of an electric resistance value. A resistive memory can be of different types, according to the phenomena used to write, store and read the information.

Resistive memories are typically made in layers located above a substrate (for example a Silicon substrate) on which the array is made. These components are said to belong to the “manufacturing unit”, that is manufactured during final manufacturing steps or even “Back-End-Of-Line” (BEOL) components, as opposed to components belonging to the initial manufacturing unit” or “Front-End-Of-Line” (FEOL) components. BEOL components, for example, are integrated between the metal interconnection levels. FEOL components are manufactured on the surface of the substrate (diodes and CMOS transistors, for example).

For example, a PCRAM (Phase Change Random Access Memory) implements the strong contrast in electronic properties between an amorphous phase and a crystalline phase of a material.

A CBRAM (Conductive Bridge RAM) implements the formation/dissolution of a conductive filament in a solid electrolyte as a result of diffusion of ions from an active electrode.

A so-called “oxide reversible dielectric breakdown” or OxRAM (Oxide RAM) memory implements reversible breakdown of a dielectric material as a function of an electrical voltage applied to this material.

A so-called magnetic memory or MRAM implements relative magnetisation between a reference magnetic layer and a programmable magnetic layer.

The use of resistive memories is proving to be a promising solution for increasing density of memory arrays. They are also being used to develop new applications such as “neuromorphic” computing and a new class of memory called “Storage Class Memory”. However, resistive memories can have different drawbacks.

In an array of memory points, a plurality of resistive memories are connected to a same row or column. However, applying an addressing voltage to the terminals of one of these memories (for example to read it) creates a non-negligible leakage current in the other memories of the same row or column. This leakage current degrades the ability to read and/or write information in one of the memories.

In order to solve this problem, it is known to add selection devices, called “selectors”, for example each connected in series with each memory (“1S1R” type arrangement). Activation of a single selector from the plurality of selectors thus enables a single memory to be selected, while the other selectors, being blocked (off), to eliminate or reduce leakage currents from the other memories.

A type of selector co-integratable in the back-end, called a “co-integratable” selector or “back-end” selector in the following, offers ease of co-integration with the memory, in series with the same, wherein its dimensions can be adjusted to the dimensions of the resistive memory. Indeed, the conducting (on) state of a back-end selector is sufficiently conductive to reduce its dimensions to the same level as those of the memory with which it can be connected in series. In addition, a back-end selector can be formed of layers deposited onto or under a memory layer and etched as a block at the same time as the memory layer. There are several types of back-end selector.

An Ovonic Threshold Switching (OTS) selector implements a characteristic property of some chalcogenide materials: under the effect of an electric field, it shifts from a resistive state to a metastable conductive state; the metastable conductive state can be maintained as long as a holding current flows in the OTS selector; otherwise, the OTS selector returns to the resistive state (off state);

An unstable conductive bridge or TS (Threshold Switch) selector implements the formation of a metastable metal filament by diffusing, under the effect of an electric field, an active electrode in an electrolyte; when the field is no longer applied, the metastable metal filament dissolves;

A MIEC (Mixed Ion-Electronic Conduction) selector implements mobility of metal ions for creating an electric current under the effect of an electric field;

A metal-insulator transition selector implements a material with high electronic correlation requiring the application of an electric field exceeding a threshold field to create an electric current, the threshold field being a function of the Coulomb repulsion forcing the free electrons of said material to be located;

Finally, a Schottky barrier or tunnel barrier selector implements a high degree of non-linearity in its current-voltage characteristic to achieve the desired “selection” effect.

A memory point comprising a “back-end” selector has a reduced overall size and is easy to manufacture (it can be etched at the same time as the resistive memory part of the memory point). However, good functionality of the assembly relies on matching in the electrical properties of the selector and the memory.

There is therefore a need for a non-volatile resistive memory device, with a selector, which is of low overall size, is convenient to manufacture, and wherein the electrical properties of the memory and the selector can each be adjusted independently.

### SUMMARY OF THE INVENTION

The invention relates to an assembly comprising at least two non-volatile resistive memories electrically disposed in parallel with each other and each electrically connected in series to a selective layer respectively forming at least two selectors, each dedicated to one of the memories, the assembly including:
a first planar stack, comprising:
   a first active layer which extends in parallel to a given horizontal plane, the first active layer being said selective layer; and
   a first upper electrode and a second upper electrode which both extend on the first active layer and which are electrically insulated from each other, the first upper electrode being laterally delimited by one side surface, the second upper electrode being laterally delimited by another side surface, an insulating layer extending between a part of the side surface of the first upper electrode and a part of the side surface of the second upper electrode to electrically insulate the first upper electrode from the second upper electrode;
a second stack, which extends obliquely or perpendicularly to said plane, comprising a second active layer, at least a part of the second active layer extending opposite another part of the side surface of the first upper electrode, the second active layer being in electrical contact with the first upper electrode, the second active layer being a non-volatile resistive memory layer;
a third stack, which extends obliquely or perpendicularly to said plane, comprising a third active layer, at least a part of the third active layer extending opposite another part of the side surface of the second upper electrode, the third active layer being in electrical contact with the second upper electrode, the third active layer being a non-volatile resistive memory layer;
the second and third active layers being disjoint, with no direct electrical contact therebetween.

Each upper electrode is electrically connected to a conduction region of the first active layer, i.e. the selective layer of the assembly. By conduction region or conduction channel, it is meant a portion of active layer where the resistivity can vary as a function of an applied voltage or a current flowing therethrough. In particular, this is a portion where the creation/destruction of a conductive structure such as a conduction filament is favoured.

As the first and second upper electrodes are separated from each other, they are connected to conduction regions that are also separated from each other. Thus the first active layer comprises two separate, independently operable conduction regions.

Since the first active layer is a selective layer, the two separate conduction regions of the first layer thus form a first selector and a second selector, which are distinct and independently operable. Thus, each selector is connected in series with a vertical (or at least oblique) stack, acting as a memory. The assembly according to the invention therefore comprises two independently addressable selector/memory assemblies 1S1R, enabling two distinct pieces of information to be stored in a non-volatile manner. In other words, the assembly is of the nSnR type, where n is at least equal to two.

The dimensions of the first selector partly depend on the surface area of the first upper electrode extending on the first active layer. The greater said surface area, the greater the dimensions of the first selector, especially in parallel to the given horizontal plane. Similarly, the dimensions of the second selector partly depend on the (planar) surface of the second upper electrode extending on the first active layer. It is thus possible to adjust dimensions of the first and second selectors independently, by adjusting the planar surface areas of the first and second upper electrodes extending on the first active layer.

The first upper electrode is also electrically connected, via its side surface, to a conduction region of the second active layer. The conduction region of the second active layer therefore forms a first memory. The vertical dimensions of the first memory partly depend on the surface area of the first upper electrode in contact with the second active layer. For example, it is proportional to a thickness of the first upper electrode. The greater said thickness, the greater the dimensions of the first memory. It is thus possible to adjust dimensions of the first memory by adjusting thickness of the first electrode. The thickness of the first upper electrode, on the one hand, and its arrangement (in particular its extent) on the first active layer, on the other hand, can be adjusted independently of each other (stated differently, the thickness of this electrode can be adjusted independently of the side dimensions of the conduction zone of the first selector). The dimensions of the first selector and the first memory can therefore be adjusted independently.

Electrical properties of the first memory and the first selector partly depend on their dimensions. Indeed, the current passing through the memory partly depends on the size of the memory. Furthermore, for PCRAM-type memories, for example, the programming current is proportional to the surface area of the electrode against which it extends. Similarly, the threshold current of the selector also partly depends on its dimensions. And, for an OTS type selector, the holding current can be reduced by reducing the dimensions of the selector, especially when these are less than a critical dimension in the order of 80 nm. The leakage currents of a MIEC-type selector also partly depend on the size of the electrode against which the selector extends. Thus, electrical properties of the first memory, and those of the first selector can be adjusted independently, in this particular architecture, due to the fact that the surface areas (or effective surface areas) of these elements can be adjusted independently of each other.

The same reasoning applies to a conduction region of the third active layer, forming a second memory. Electrical properties of the second selector and the second memory can each be adjusted independently by adjusting a thickness of the second upper electrode and its arrangement on the first active layer.

As explained in detail with reference to the figures, the oblique orientation with respect to said plane, for example vertical, of at least some of the second and third active layers, combined with the use of a same first, horizontal, selective layer, results in a highly satisfactory compactness for the assembly.

In addition, this particular geometric arrangement surprisingly makes it possible to obtain effective surface areas (typically superimposed surface areas between electrodes or electrical contacts) that can be smaller than a minimum surface accessible at first sight for an etching fineness F, i.e. smaller than F2.

For each of the memories of the assembly, oriented obliquely with respect to the horizontal plane, the surface area of the memory facing the upper electrode under consideration embraces part of the perimeter of this upper electrode. This surface area is therefore equal to the length of the memory/electrode portion in contact multiplied by the thickness of the electrode.

For example, when the memory embraces three of the four sides of the upper electrode under consideration, its surface area S is equal to:

$$S = w ( L + 2 l )$$

where L is the length of one long side of the electrode, for example equal to fineness F, l is the length of two short sides of the electrode, for example equal to F/2 and w is the thickness of the electrode, for example equal to F/4. The surface area S (effective surface area of the memory) is according to this example equal to:

$$S = 1 / 2 {F}^{2} < {F}^{2}$$

Memories, for example of the OxRAM type, advantageously benefit from this reduction in surface area. Indeed, they can show greater resistance in the high state as their surface area is reduced. Modifying the resistance at the high state of the memory (so as to increase it) especially makes it possible to increase the reading window of the selector/memory assembly.

Similarly, each selector can also have a reduced surface area, also less than F². Indeed, the manufacture of a selector according to prior art, i.e. aligned in the plane, is limited by the etching fineness F. The smallest surface area of a selector according to prior art that can be manufactured is therefore greater than or equal to F².

For each of the two selectors in the selective stack, its surface area is equal to the surface area of an upper electrode extending on the first active layer. For example, for an upper electrode with a long side having length F and a short side having length F/2, the surface area S of the selector is also equal to:

$$S = 1 / 2 {F}^{2} < {F}^{2}$$

Furthermore, in this geometry, the effective surface area of the selector can be made even smaller by a lateral offset between the upper electrode and lower electrode.

Selectors, for example ovonic selectors, advantageously benefit from this reduction in surface area, making it possible, for example, to reduce their leakage current and also their threshold and holding currents when their dimensions are below a limit value, generally in the order of 80 nm.

Further to the characteristics just discussed in the previous paragraph, the assembly according to the invention may have one or more additional characteristics from among the following, considered individually or according to any technically possible combinations:
the assembly comprises a lower electrode, which extends beneath the first active layer, in parallel thereto, and which is in electrical contact with a lower face of the first active layer;
at least a part of the first upper electrode is located vertically above the lower electrode, superimposed on the lower electrode, in a projection along a direction perpendicular to said plane;
at least a part of the second upper electrode is located in vertical alignment with the lower electrode, superimposed on the lower electrode, in a projection along a direction perpendicular to said plane;
at least one of the upper electrodes is only partially superimposed on the lower electrode;
the first and second upper electrodes are separated from each other, along a given horizontal direction, by a given spacing;
along said direction, the first upper electrode is superimposed on the lower electrode over a distance which is less than said spacing;
along said direction, the first upper electrode is superimposed on the lower electrode over a distance which is greater than said spacing;
the first active layer laterally extends beyond the lower electrode, protruding on a dielectric layer which surrounds the lower electrode;
the first active layer is laterally delimited by a side surface, and the assembly further comprises an electrically insulating spacer which extends at least against the side surface of the first active layer, at least partly covering this side surface;
the spacer also covers, only partly, the side surface of at least one of the first and second upper electrodes;
the first and second upper electrodes are in direct contact with the first active layer (i.e. with no intermediate layer therebetween);
the first planar stack comprises an insulating layer which extends on the first and second upper electrodes;
the insulating layer is divided into a first part and a second part, with the first part of the insulating layer covering the first upper electrode and the second part of the insulating layer covering the second upper electrode;
the assembly comprises a fourth, planar, stack disposed on the insulating layer, the fourth stack comprising:
   a fourth active layer extending in parallel to said plane, the fourth active layer being a selective layer;
   third and fourth electrodes which extend in parallel to said plane, between the fourth active layer and the insulating layer, and which are electrically insulated from each other, the third electrode being laterally delimited by one side surface, the fourth electrode being laterally delimited by another side surface, an insulating layer extending between a part of the side surface of the third electrode and a part of the side surface of the fourth electrode to electrically insulate the third electrode from the fourth electrode;
the second active layer extends beyond the side surface of the first upper electrode, extending along a part of the side surface of the third electrode; and
the third active layer extends beyond the side surface of the second upper electrode, extending along a part of the side surface of the fourth electrode;
the fourth stack comprises:
   a fifth electrode, which extends above the fourth active layer, in electrical contact with the fourth active layer, and
   a third electrically insulating spacer which covers a side surface of the fifth electrode;
the first active layer, common to the second and third stacks, is continuous in one piece;
the first active layer is divided into a first part and a second part, which are disjoint, the first part of the active layer extending beneath the first upper electrode, the second part of the active layer extending beneath the second upper electrode.

The invention further relates to a resistive memory array comprising a plurality of assemblies as described above, wherein for each assembly:
the first planar stack of the assembly is electrically connected to an addressing row of the array,
the second and third vertical stacks of the assembly are electrically connected, respectively, to two addressing columns of the array, the two addressing columns being distinct.

The invention also relates to a method for manufacturing an assembly comprising at least two non-volatile resistive memories electrically disposed in parallel with each other and each electrically connected in series to a selective layer respectively forming at least two selectors, each dedicated to one of the memories, the method comprising the following steps of:
forming a first planar stack comprising:
   depositing a first active layer which extends in parallel to a given horizontal plane, the first active layer being said selective layer; and
   depositing a first upper electrode and a second upper electrode which both extend on the first active layer and which are electrically insulated from each other, the first upper electrode being laterally delimited by one side surface, the second upper electrode being laterally delimited by another side surface, an insulating layer extending between a part of the side surface of the first upper electrode and a part of the side surface of the second upper electrode to electrically insulate the first upper electrode from the second upper electrode;
forming a second stack, which extends obliquely or perpendicularly to said plane, comprising a second active layer, at least a part of the second active layer extending opposite another part of the side surface of the first upper electrode, the second active layer being in electrical contact with the first upper electrode, the second active layer being a non-volatile resistive memory layer;
forming a third stack, which extends obliquely or perpendicularly to said plane, comprising a third active layer, at least a part of the third active layer extending opposite another part of the side surface of the second upper electrode, the third active layer being in electrical contact with the second upper electrode, the third active layer being another non-volatile resistive memory layer.

The steps of forming the second and third stacks can be performed by carrying out the following steps of:
conformally depositing an overall active layer, a first part of the overall active layer extending facing the side surface of the first upper electrode, the first part of the overall active layer being in electrical contact with the first upper electrode, a second part of the overall active layer facing the side surface of the second upper electrode, the second part of the overall active layer being in electrical contact with the second upper electrode;
separating the overall active layer into at least said second active layer and said third active layer, which are disjoint.

Optional characteristics set forth above in terms of the device (for the assembly described above) may also apply to the method just set forth.

The invention and its different applications will be better understood upon reading the following description and upon examining the accompanying figures.

### BRIEF DESCRIPTION OF THE FIGURES

The figures are set forth by way of indicating and in no way limiting purposes of the invention. Unless otherwise specified, a same element appearing in different figures is identified by the same reference sign.

FIG. 1a and FIG. 1b schematically represent, in a cross-section view and top view, a first embodiment of an assembly comprising two non-volatile resistive memories and two selectors according to the invention.

FIG. 2 schematically represents one embodiment of an array of assemblies according to the invention.

FIG. 3 schematically represents, in a cross-section view, a development of the first embodiment of the assembly according to the invention.

FIG. 4 schematically represents, in a cross-section view, a second embodiment of the assembly according to the invention.

FIG. 5 schematically represents, in a cross-section view, a third embodiment of the assembly according to the invention.

FIG. 6 schematically represents, in a cross-section view, a fourth embodiment of the assembly according to the invention.

FIG. 7a to FIG. 11b schematically represent, in a cross-section view and top view, steps in the method for manufacturing an assembly according to the invention.

### DETAILED DESCRIPTION

The invention especially relates to an assembly 1 comprising at least two non-volatile resistive memories and two selectors, each associated in series with one of these memories. Assembly 1 according to the invention makes it possible to adjust electrical properties of these memories and these selectors independently, while having a reduced overall size.

For this, assembly 1 combines a first planar stack 10, parallel to a given horizontal plane P, and at least two distinct stacks 20, 30, at least a part of which extends obliquely with respect to the plane P in question, for example vertically. In the following, the term ‘planar’ or ‘horizontal’ will be used to indicate an orientation parallel to said plane P (for example parallel to within better than 5 degrees). The plane P in question is, for example, parallel to a substrate on which assembly 1 is made. Oblique means an orientation at an angle of 90°+45° to plane P, in other words an angle of between 45° and 135° to plane P. Vertical is taken to mean an orientation at an angle of 90°+30° to plane P, preferably 90°+5°. Herein, in the examples described here with reference to the figures, at least a part of the second and third stacks 20, 30 extend vertically (perpendicularly to plane P). Alternatively, however, each of these two stacks could be oriented differently, extending for example in parallel to a plane making an angle of 60 degrees with said horizontal plane P (or, more generally, an angle of between 60 and 80 degrees, for example).

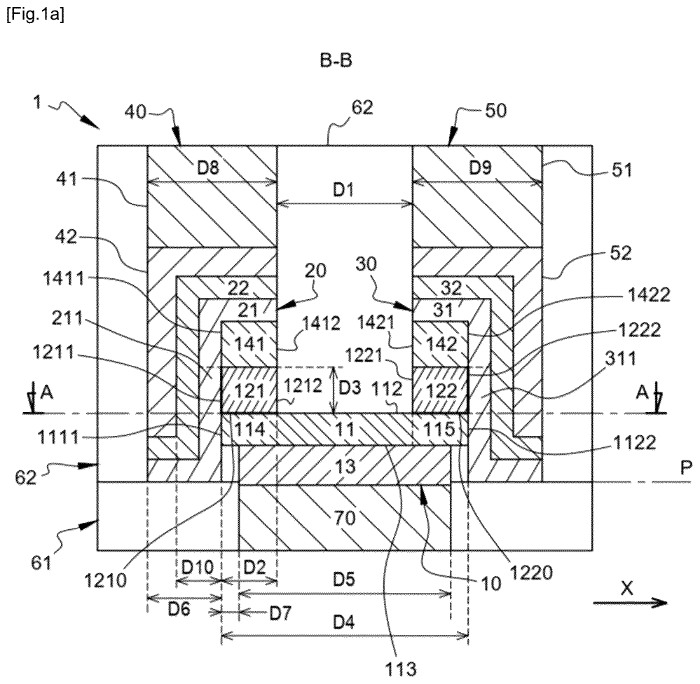

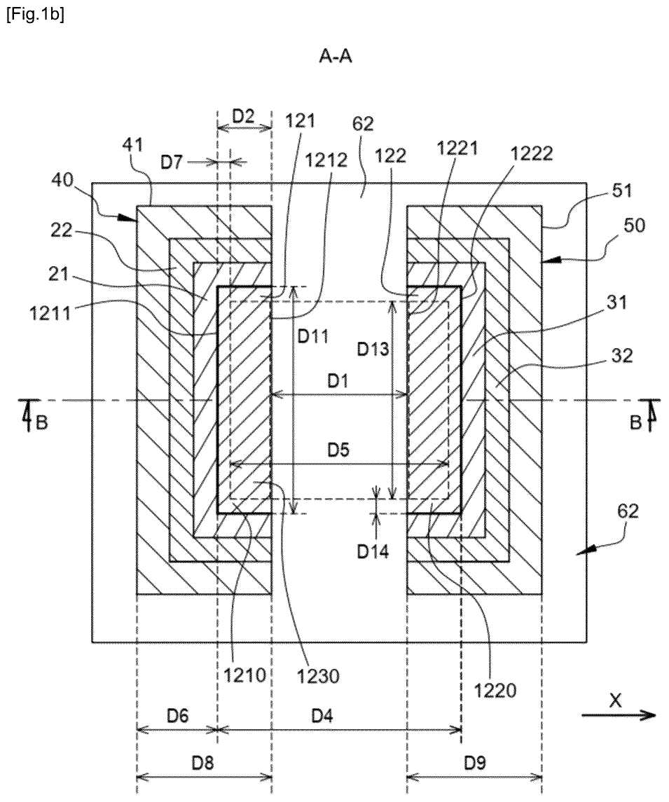

In the first, second, third and fourth embodiments described below (and represented, respectively, in FIGS. 1a, 4, 5 and 6), the first planar stack 10 is a selective stack (for example of the “back-end” type and co-integrable in series with the memories in the BEOL), while the two “vertical” stacks 20, 30 are memory stacks. In practice, such a configuration, in which the second and third stacks are memory stacks while the first stack is a selective stack, makes it possible to limit surface area occupied by the assembly 1, in parallel to plane P. Indeed, memory stacks are generally less thick than the selective stack.

The first planar stack 10 comprises two upper electrodes 121, 122, separated from each other, with no direct electrical contact therebetween. Each upper electrode 121, 122 is electrically connected to one of the vertical stacks 20, 30. This arrangement corresponds to two independent 1S1R type memory/selector circuits.

From an electrical point of view, the second and third stacks 20, 30 are, as it were, disposed in parallel with each other, since, on the one hand, they are both connected in series to a common selective stack. It should nevertheless be noted that, on the other hand, these two memory stacks 20, 30 are connected to distinct electrical contacts (40 and 50), electrically insulated from each other.

As already indicated, at least a part of the memory stack 20 extends in parallel to a vertical plane. This part of the stack 20 extends opposite a first part 1211 of a side surface 1211, 1212 which laterally delimits the first upper electrode 121. This part of the stack 20 here extends in parallel to this first part 1211 of side surface (in parallel thereto, to better than 5 or 10 degrees, for example).

Similarly, at least a part of the memory stack 30 extends in parallel to a vertical plane. This part of the stack 30 extends opposite a second part 1222 of a side surface 1221, 1222 which laterally delimits the second upper electrode 122. This part of the stack 30 here extends in parallel to this second part 1222 of the side surface.

In assembly 1, the different layers (including the electrodes) which extend in parallel to plane P are each laterally delimited by one (or possibly more) side surface(s) which is (are) vertical or at least oblique with respect to plane P. This side surface or surfaces are also referred to hereinafter as the flank(s). In the following, for some layers, it is indicated that the layer under consideration is laterally delimited by a side surface comprising two parts (i.e.: by a first and second flank, here), in practice located opposite to each other. The side surface in question may nevertheless be continuous, and go all around the electrode without discontinuity, for example when the edge of this layer is circular (this side surface then being cylindrical); in this case, the two portions in question correspond to two portions of this continuous surface, situated opposite to each other. These two parts of the side surface of the layer may also correspond to two distinct faces of the perimeter of the layer in question, when this perimeter is, for example, rectangular, as shown here (rectangular seen from above the layer).

FIG. 1a and FIG. 1b schematically represent, respectively in a cross-section view and a side view, the first embodiment of assembly 1. The first stack 10 especially comprises:
a first active layer 11;
the first upper electrode 121, mentioned above; and
the second upper electrode 122.

The first active layer 11 extends in parallel to the plane P. The plane P corresponds, for example, to the surface of a dielectric layer 61 on which the assembly 1 may rest (it should be noted, however, that, at the end of manufacture, the dielectric layer 61 may form part of an overall protective dielectric coating in which the assembly is coated).

The first and second upper electrodes 121, 122 extend on the first active layer 11. The first active layer 11 is delimited by an upper surface 112 and a lower surface 113, opposite to the upper surface 112. Each upper electrode 121, 122 extends, for example, on the upper surface 112 of the first active layer 11, against it. The lower surface 113 of the first active layer 11 at least partly rests for example on the dielectric layer 61, in parallel to the plane P.

The first upper electrode 121 is laterally delimited by the aforementioned side surface. Said side surface comprises a first part (or portion) referred to hereinafter as the first flank 1211. The first upper electrode 121 may, as here, have an overall rectangular shape. It is then laterally delimited by four parts of the side surface (including the first flank 1211, and another part, opposite to it, called the fifth flank 1212 in the following), corresponding to the four sides of this rectangle.

Similarly, the second upper electrode 122 is laterally delimited by the aforementioned side surface, a part of which is referred to as the second flank 1222. The second upper electrode 122 may also have an overall rectangular shape. It is then laterally delimited by four parts of said side surface (including the second flank 1222, and another part, opposite to it, referred to hereinafter as the sixth flank 1221), corresponding to the four sides of this rectangle.

The first active layer 11 is also laterally delimited by a side surface, comprising at least two parts, opposite to each other, called third flank 1111 and fourth side 1122. The third and fourth flanks 1111, 1122 may be located as an extension of the first and second flanks 1211 and 1222 of the first and second upper electrodes 121, 122; in this case, the first flank 1211 (of the first upper electrode 121) and the third flank 1111 (of the first active layer 11) form the same, overall, flank of the first planar stack 11 as a whole (resulting from overall etching of the first stack); similarly, the second and fourth flanks 1222, 1122 then form another, overall, flank of the first stack as a whole. Here, the first active layer also has an overall rectangular shape.

The first planar stack 10 performs a selection function and the first active layer 11 is a selective layer. This means that it is configured to modify its conductivity as a function of a voltage applied between its upper and lower surfaces 112, 113, and/or as a function of an electric current flowing between these surfaces 112, 113. A threshold voltage is defined above which the first active layer 11 is in an “off” state. This means that at least a part of the first active layer 11 is then conductive. By conductive, it is meant that its resistance is less than 10 kΩ. Below the threshold voltage, the selective layer 11 is in a so-called “off” state. This means that the resistance of the first active layer 11 is, for example, greater than or equal to at least 100 kΩ. Some types of active layer 11 may, however, have a resistance that varies as a function of the voltage applied between its upper and lower surfaces 112, 113. The resistance may exponentially vary so that it is in the order of 10 kΩ or a few tens of kΩ just before switching from the off state to the on state. The on state is preferably metastable. This means that the first active layer 11 is initially in the off state and does not present an on state until a voltage applied between its upper and lower surfaces 112, 113 becomes greater than the threshold voltage. The first active layer 11 can keep an on state as long as a current or voltage applied to said layer 11 is greater than a given holding current.

The first active layer 11 comprises, for example, a chalcogenide, for example an alloy based on selenium, germanium, antimony and nitrogen. In which case, the first planar stack 10 is an Ovonic Threshold Switching (OTS).

The first active layer 11 may also comprise a material such that the first planar stack 10 is a TS (Threshold Switch) selector, a MIEC (Mixed Ion-Electronic Conduction) selector or a metal-insulator transition selector. In these cases, the first and second upper electrodes can be active electrodes in the selective stack.

The first upper electrode 121 is conductive. It includes one or more layers, parallel to the plane P. One of these layers may be a metal layer. Another of these layers may be a layer for avoiding diffusion of species into the first active layer 11. By way of example, this electrode may comprise a carbon layer interposed between a titanium nitride layer and the first active layer 11.

In this first embodiment, the first upper electrode 121 extends on a first portion 1210 only of the upper surface 112 of the first active layer 11, in particular at a first portion 114 of the first active layer 11 (part of the portion 114 being located in vertical alignment with a lower electrode 13).

The second upper electrode 122 is also conductive. In the same way as the first upper electrode 121, it includes one or more layers parallel to the plane P. In this first embodiment, the second upper electrode 122 extends on a second portion 1220 of the upper surface 112 of the first active layer 11, in particular at a second portion 115 of the first active layer 11 (part of the second portion 115 also being located in vertical alignment with the lower electrode 13).

The fifth and sixth flanks 1212 and 1222 face each other and are at least spaced apart by a first distance D1 (corresponding, for example, to the width of a trench separating these two electrodes, obtained by etching). The fifth and sixth flanks 1212 and 1222 are also separated by an insulating layer 62, electrically insulating the electrodes 121, 122 from each other. Indeed, the assembly 1 completed is buried in a dielectric material 62 enabling different elements to be insulated from each other, including the first and second electrodes 121, 122.

As already indicated, the second vertical stack 20 here acts as a memory. It enables non-volatile information to be stored. The information is encoded, for example, in the form of a resistance value of an active layer of said second vertical stack 20. The second vertical stack 20 may be of the PCRAM, CBRAM, OxRAM or MRAM type as described in the introduction of prior art. For this, the second vertical stack 20 comprises at least one second active layer 21. The second active layer 21 may have a so-called “low” state, i.e. a low resistance, for example less than a resistance in the order of 10 kΩ, or even 10 kΩ, or a so-called “high” state, i.e. a high resistance, for example greater than 50 kΩ. The second active layer 21 shifts from the high state to the low state when a voltage applied to this layer or a current flowing through the layer exceeds a programming voltage/current, also known as the “set” voltage/current. The second active layer 21 shifts from the low state to the high state when a voltage or current applied to the layer exceeds an erase voltage/current, also called a reset voltage/current. The second active layer 21 comprises, for example, a hafnium oxide layer (in contact with a titanium layer acting as a tank for oxygen vacancies), in which case the second vertical stack 20 performs the OxRAM function.

Similarly, the third stack 30 comprises at least a third active layer 31, for encoding information in the form of a resistance value. The electrical characteristics of the second and third active layers 21, 31, including at least the programming and erase voltages/currents, are similar or even identical.

The reduction in the overall size of assembly 1 especially results from the sharing of a same selective stud for two memories, and from the oblique orientation of at least a part of the second active layer 21, located opposite the first flank 1211 of the first upper electrode 121, and of at least a part of the third active layer 31, located opposite the second flank 1222 of the second upper electrode 122.

The first upper electrode 121 electrically connects the first active layer 11 with the second active layer 21. Similarly, the second upper electrode 122 electrically connects the first active layer 11 to the third active layer 31. Thus, the first active layer 11 is common to the second and third vertical stacks 20, 30. In other words, it is the same first active layer 11 that is electrically connected to the second active layer 11 on the one hand and to the third active layer 31 on the other hand. The second and third active layers 21, 31 are separate from each other. They are electrically insulated from each other because they are only in contact via the first active layer 11.

By electrically insulated, it is meant that there is no direct electrical contact therebetween. In other words, there is no element, being conductive in all circumstances (for example metal), directly connecting them.

The second active layer 21 can be electrically connected between a first upper electrical contact 40 and the first upper electrode 121. Similarly, the third active layer 31 can be electrically connected between a second, upper electrical contact 50 and the second, upper electrode 122. The first and second contacts 40, 50 are electrically insulated from each other.

The memory and selector assembly 1 may be buried in a dielectric material, for example an insulating oxide filler 62 such as silicon oxide.

The first upper electrode 121 extends on the first portion 1210, referred to as the first surface, of the upper surface 112 of the first active layer 11. At least a part of the first portion 114 of the first active layer 11 is located in vertical alignment with the first surface 1210. The first upper electrode 121 influences electrical conduction at the first portion 114. For example, the application of a voltage between the first upper electrode 121 and the lower surface 113 of the first active layer 11 enables the first portion 114 of the active layer to shift from the off state to the on state (provided that the voltage applied is greater than a threshold voltage of the material under consideration). The first portion 114 can therefore perform a local selection function.

In the same way, the second upper electrode 122 influences electrical conduction at the second portion 115 of active layer 11. The second portion 115 can therefore also perform a selection function locally.

Since the first and second upper electrodes 121, 122 are separated from each other, the first and second portions 114, 115 of the first active layer 11 are therefore also separated from each other (unless the dimensions of the conduction region are close to or greater than the distance separating the two upper electrodes, in which case the first and second portions 114, 115 of the first active layer 11 may be too close and it may be desirable to separate the active layer 11 into two distinct parts, as in the case of FIG. 5, in order to obtain two independent selectors). The first active layer 11 therefore comprises two portions 114, 155, each of which performs the selection function and can be operated independently. In other words, the first planar stack 10 comprises two selectors. Each selector is dedicated to a memory stack.

Assembly 1 thus comprises two 1S/1R type memory/selector circuits (the selector being connected in series with the resistive memory element), operable independently of each other.

The arrangement of the first portion 114 depends on the arrangement of the first upper electrode 121 on the first active layer 11 and therefore on the position and dimensions of the first surface 1210. In the example of [FIG. 1a], the first upper electrode 121 extends along an edge of the upper surface 112 of the first active layer 11. The edge in question is especially disposed in vertical alignment with the first and third flanks 1111, 1211. The first upper electrode 121 extends from this edge over a second distance D2. The second distance D2 is measured perpendicular to said edge.

The first surface 1210 therefore also extends, from this edge, over the second distance D2.

Electrical properties of the first portion 114 partly depend on its dimensions. The particular structure of assembly 1 thus makes it possible to adjust electrical properties of the selector associated with the first portion 114, as a function of the arrangement of first upper electrode 121 on first active layer 11, in particular as a function of the extent of this first electrode, and as a function of its positioning more or less in vertical alignment with the lower electrode 13.

Similarly, the assembly 1 enables electrical properties of the selector associated with the second portion 115 to be adjusted as a function of the arrangement of the second upper electrode 121 on the first active layer 11.

A portion of the second active layer 21, referred to as the third portion 211, is in contact with the first flank 1111 of the first upper electrode 121. The first upper electrode 121 can also influence electrical conduction at this third portion 211. For example, the application of a voltage between the first upper electrode 121 and an opposite surface of the second active layer 21 enables the third portion 211 to shift from its highly resistive state to its low resistive state. The third portion 211 therefore locally provide a non-volatile memory function.

Electrical properties of the third portion 211 also partly depend on its dimensions. The dimensions of the third portion 211 especially depend on the surface (i.e. the area) of the first flank 1111. Adjustment of the surface area of the first flank 111, obtained for example by adjusting the thickness of the layer 121, therefore makes it possible to adjust electrical properties of the non-volatile memory associated with the third portion 211. The surface area of the first flank 1111 can, for example, be adjusted as a function of the thickness D3 of the first upper electrode 121.

The assembly 1 therefore enables dimensions of the selector associated with the first portion 111 and the non-volatile memory associated with the third portion 211 to be adjusted independently. Thus, electrical properties of said selector and said memory can be independently adjusted.

The same reasoning applies to the fourth portion 311 (portion of the third active layer 31). By adjusting the area (i.e. the surface extent) of the second flank 1222, it is possible to adjust electrical properties of a non-volatile memory associated with the fourth portion 311.

The assembly 1, comprising two 1S1R circuits, enables electrical properties of each selector and each memory to be adjusted independently.

The first planar stack 10 comprises a lower electrode 13, in contact with the lower surface 113 of the first active layer 11. A part of the first upper electrode 121 extends opposite a part of the lower electrode 13. In other words, the part of the first upper electrode 121 is superimposed by vertical projection to the lower electrode 13. By vertical projection, it is meant along a vertical direction as previously defined.

Here, only part of the first upper electrode 121 is superimposed on the lower electrode 13. Thus, the fifth flank 1212 is located above the lower electrode 13, in vertical alignment with it, whereas the first flank 1211 is laterally offset with respect to the lower electrode 13 and is not located in vertical alignment with the lower electrode 13, above it. In vertical alignment is meant to be aligned along a vertical direction. The selector associated with the first portion 114 of the active layer 114 is then established between the facing surfaces 1230 (i.e.: in superimposition) of the first upper electrode 121 and the lower electrode 13. The lateral offset between the first upper electrode 121 and the lower electrode 13 makes it possible (as does the reduced width D2 of the upper electrode) to obtain, for the selector in question, an effective surface area (in this case a surface on which there is superimposition between the electrodes 121 and 13) smaller than F², where F is an etching fineness of the manufacturing technology considered at the level considered in the BEOL. The fact that it is possible to obtain a surface area smaller than F² is surprising at first sight. This is especially due to the particular geometrical structure of the assembly 1, and to the fact that alignment accuracies during etching or deposition (accuracy better than 15 nm, for example) can be better than fineness F (equal to around forty nm, for example).

The area S₁₂₃₀ of the surface 1230 facing the first electrode 121 can then be expressed as (see FIG. 1b):

$${S}_{1230} = D 13 \times ( D 2 - D 7 )$$

Considering, for example, D2=2/3 F, D7=1/2 F and D13=2 F, the surface area 1230 is then equal to 1/3 F², which is much less than F² (D13 is the width of the lower electrode 13, in parallel to the plane P, and along a direction perpendicular to X—therefore along a direction perpendicular to that corresponding to the width D5).

Similarly, only a part of the second upper electrode 122 extends opposite a part of the lower electrode 13 (or by vertical projection on it), in vertical alignment with it. The sixth flank 1221 is located above the lower electrode 13, in vertical alignment with the same, while the second flank 1222 is laterally offset with respect to the lower electrode 13: it is not located in vertical alignment with the lower electrode 13 (it is not located above the same).

Some variability in electrical characteristics of the first planar stack 10 may be caused by manufacturing steps of said stack 10 or vertical stacks 20, 30 introducing defects in a part of the first active layer 11. The defects are generally located at the flanks of the first active layer 11 (i.e. especially at the third and fourth flanks 1111, 1122), exposed to etching or deposition steps. Electrical characteristics at these flanks are then modified locally. It is then planned to move the third and fourth flanks 1111, 1122 away from each other, so that they are separated by a third distance D4, greater than a width D5 of the lower electrode 13. Thus, each selector associated with the portions 114, 115 of the first active layer, is away from the flanks 1111, 1122 of the first active layer 11. They are thus little influenced by electrical characteristics at the third and fourth flanks 1111, 1122. Each selector thus has minimal variability in its electrical characteristics.

The first distance D1 between the first and second upper electrodes 121, 122 is, for example, between 40 nm and 90 nm. Indeed, in a first ovonic active layer 11, a metastable conduction channel may have a planar extent of between 40 nm and 60 nm (and rarely more than 80 nm). By thus increasing the first distance D1 separating the upper electrodes, the influence that the selectors can have on each other is reduced.

The third distance D4 separating the third and fourth flanks 1111, 1122 is for example between 60 nm and 110 nm, or even between 80 nm and 100 nm. This reduces variability in the electrical characteristics of the selective stack, set by those of the conduction channels located away from the flanks (away from the edges).

The partly vertical orientation of the second and third stacks 20, 30, and the use of a common, planar first active layer 11, means that the third and fourth flanks 1111, 1122 can be spaced apart from each other, as indicated above, to reduce variability problems, without increasing overall size of the assembly 1, compared to 1R1S devices of prior art, at least from the point of view of overall size along direction X represented in FIG. 1a (direction parallel to plane P, and directed from the first flank towards the second flank, here perpendicular to each of these two sides). This aspect is explained in more detail below.

In the direction X, each vertical stack 20, 30 extends, from the first flank 1111 of the first upper electrode 12, over a fourth distance D6. In the first embodiment, this distance corresponds as it were to the total thickness of the second stack 20 and of an optional metal layer 42 covering it. Furthermore, the first flank 1111 is laterally offset, with respect to the lower electrode 13, by a fifth, non-zero distance D7. Similarly, the second flank 1222 is laterally offset, with respect to the lower electrode 13, by the same fifth distance D7. Therefore D4=D5+2·D7. The first upper electrode 121 is therefore only partially superimposed on the lower electrode 13.

In practice, the width D5 of the lower electrode 13 is at least equal to the etching fineness, F, which is 40 nm for example. The fineness especially imposes a minimum width on a lower via 70, passing through the dielectric layer 61 to connect the lower electrode 13. The width D5 of the lower electrode 13 and a width of the lower via 70 are equal to each other. The width D5 is therefore at least equal to the fineness F.

The first distance D1 separating the first and second upper electrodes 121, 122 advantageously depends on the width D5 of the lower electrode 13. In order to allow face-to-face contact between the upper electrodes 121, 122 and the lower electrode 13, the first distance D1 is preferably strictly less than the width D5. In practice, the conduction channels can still be established if there is no face-to-face contact between the upper electrodes 121, 122 and the lower electrode 13. However, this may increase variability in the conduction channels established in the first active layer 11.

Similarly, the first and second electrical contacts 40, 50 respectively have a width D8 and D9 at least equal to this fineness F (i.e.: limited by the fineness F), and separated by the first distance D1.

Dimensioning the assembly so that the sum D6+D2 is, as here, less than or equal to the width D8 (width along the direction X) of the first upper contact 40 thus enables the second stack 20 to be housed beneath this contact, as well as the part of the first planar stack 10 which laterally projects beyond the lower electrode 13. The overall size of assembly 1 takes account of an additional distance, due to the space separating the assembly from its close neighbours (known as the “metal pitch”). Said distance is equal to F (F/2 on each side of the assembly 1). Thus, along direction X, the overall size is 4F, even though the first active layer 11 has a lateral extension greater than F (to limit the undesirable influence of the layer edges).

By way of example, and depending on the etching fineness F, the assembly 1 may have the following dimensions:

$$D 1 = F ;$$

$$D 2 = 3 / 4 F ;$$

$$D 3 = 10 nm ;$$

$$D 4 = 2 \text{.5} F ;$$

$$D 5 = 1.5 F ;$$

$$D 6 = 3 / 4 F ;$$

$$D 7 = 1 / 2 F ;$$

$$D 8 = D 9 = 1.5 F ;$$

$$D 10 = 10 nm ;$$

$$D 11 = 2.5 F ;$$

$$D 13 = F ; and$$

$$D 14 = 1 / 2 F .$$

D11 is the width of the upper electrodes 121, 122, is parallel to the plane P, and along a direction perpendicular to X-thus along a direction perpendicular to that corresponding to the width D5. The side surface of the upper electrodes 121, 122 is laterally offset with respect to the lower electrode 13 by a distance D11 along the direction perpendicular to X.

The total surface area STOT occupied by the assembly 1 (i.e. its footprint, including a peripheral zone surrounding the assembly, and which stops halfway between this assembly and neighbouring assemblies) can be expressed as:

$${S}_{T O T} = ( M P + D 8 + D 9 + D 1 ) \times ( M P + D 13 + 2 * D 14 )$$

where MP is a space between each assembly, called a metal pitch, for example equal to F.

In practice, D14 is equal to D7. The total surface area S_{TOT} is then equal to 15 F², for these example values. As assembly 1 comprises two 1S₁R circuits, an equivalent occupied surface area S_{1S1R}, for a single circuit 1S₁R is therefore equal to 7.5×F², here. This is greater than the surface area occupied by a 1S₁R circuit in a conventional purely planar design, for which this surface area may be 4×F² (comprising the peripheral zone mentioned above, which surrounds the memory point). On the other hand, the arrangement set forth here offers the advantage of being able to adjust, independently, the surface areas of each memory and each selector (and to have effective surface areas, for the active zones, which are less than F²).

Viewed in cross-section, the second active layer 21 comprises, for example, a vertical portion and two planar portions at each of its ends. Seen in cross-section view, it thus forms an ‘S’ which can be housed beneath the first contact 40, in line with it, without laterally protruding therefrom. In line with is meant to be in vertical alignment.

The two planar portions of the active layer 21 are optional. The active layer 21 could be entirely vertically oriented and disposed beneath the first contact 40.

In the same way, the third active layer 31, at least partly vertically oriented, allows the first active layer 11 and/or the second upper electrode 122 to extend to beneath the second contact 50 without increasing overall size of the assembly 1 (in the direction X).

The storage density offered by an array of memory points partly depends on the spacing imposed between two-by-two addressing rows and/or two-by-two addressing columns. The smaller the spacing, the greater the storage density of the final array. This spacing, which corresponds to the first distance D1 between the first and second electrical contacts 40, 50, intended to be connected to the addressing rows/columns, or which directly form these addressing rows/columns, is limited in practice by the etching fineness F.

The first planar stack 10 is also electrically connected to the lower via 70 mentioned above (or to another equivalent conductive element). The dielectric layer 61 on which the first planar stack 10 rests has this lower via 70 passing therethrough. The lower via 70 can thus be electrically connected to the lower surface 113 of the first active layer 11 through the lower electrode 13. The lower via 70 and the lower electrode 13 can moreover be made of the same material and as an extension of each other, so that they are indeed one and the same. Thus, the first active layer 11 is electrically connected in series between the first upper electrode 121 and the conductive via 70 on the one hand and the second upper electrode 122 and the conductive via 70 on the other hand. For an OTS type selector, the lower electrode may, for example, be based on titanium nitride, tantalum nitride, tungsten or tungsten nitride, or even carbon.

The upper electrodes 121, 122 and/or the lower electrode 13 may be of different types, depending, for example, on the type of material implemented by the first active layer 11. Indeed, some selectors may require the implementation of one or more so-called active electrodes in order to function. Examples include TS (Threshold Switch) or MIEC (Mixed Ion-Electronic Conduction) type selectors. Indeed, conduction in these selectors implements diffusion or migration of metal ions for forming a conductive filament in the presence of an electric field. For example, a TS type selector implements diffusion of metal ions such as silver ions. These ions can be supplied by an “active” electrode, in contact with the selective layer and which comprises silver. According to the same principle, a MIEC type selector implements diffusion/migration of metal ions such as copper ions, in which case an active electrode in contact with the selective layer advantageously comprises copper.

Depending on the direction of voltage application or current flow in the first active layer 11, either of the upper electrodes 121, 122 or/and the lower electrode 13 may be “active” with respect to the first active layer 11, i.e. include elements contributing to the conduction of the selective layer 11. The active electrode or electrodes (upper electrodes 121, 122 and/or lower electrode 13) may then comprise silver or copper. The aforementioned electrodes comprise, for example, several layers of which at least one, and if possible the layer in contact with the first active layer 11, comprises silver or copper.

The first active layer 11 may also include a plurality of layers, at least one layer of which, for example in contact with an electrode, includes elements which contribute to the conduction of the selective layer. This is, for example, a copper or silver layer extending on one of the upper or lower faces 113, 114. In order to prevent said copper or silver layer from short-circuiting the first active layer 11 itself between the upper electrodes 121, 122, it may be in two distinct parts, electrically insulated from each other. For example, the copper or silver layer has a first part disposed beneath the first electrode 121 and a second part disposed beneath the second electrode 122, the first and second parts of said layer being separated from each other by an insulating material (such as dielectric material 62).

The lower electrode 13 extends on a part, here only a part, of the lower face 114 of the first active layer 11.

The second stack 20 may, as here, comprise a conductive layer 22. The conductive layer 22 electrically connects the second active layer 21 to the first upper contact 40. Here, it is disposed between the second active layer 21 and the first upper contact 40. Here, the conductive layer 22 extends on the second active layer 21, against it. Advantageously, at least a part of the conductive layer 22 also extends in parallel to the first flank 1211 and opposite this first flank 1211. This conductive layer 22 may comprise one or more sub-layers, acting for example as a tank layer for oxygen vacancies (such a layer being made of titanium, for example), or as an insulating layer opposing the passage of oxygen (titanium nitride layer, for example), or playing yet another role in the operation of the second stack 20 as a memory stack.

The conductive layer 22 and the second active layer 21 of the second stack 20 advantageously extend, in the portion facing the first flank, at a distance D10 advantageously less than or equal to 20 nm, or even 10 nm. In other words, this is the height of the memory or selector.

Similarly, the third vertical stack 30 may comprise a conductive layer 32 electrically connecting the third active layer 31 to the second upper contact 50.

The first electrical contact 40 may comprise a first upper via 41 which extends, for example, vertically from the second stack 20. In order to improve electrical contact between the first contact 40 and the second stack 20, the same may also comprise a first metal layer 42, electrically connecting the second stack 20, interposed therebetween. The first metal layer 42 extends, for example, partly over the second stack 20, covering a vertical part and a planar part of said second stack 20. In one development, the first metal layer 42 is the conductive layer 22 of the second stack 20. The first metal layer 42 could also form one of the addressing columns of the array, the via 41 being a connection via of this column, possibly offset with respect to the assembly 1.

Similarly, the second electrical contact 50 may comprise a second upper via 51 extending, for example, vertically from the third stack 30. It may also comprise a second metal layer 52 electrically connecting the third stack 30. The second metal layer 52 may also extend on the third stack 30, covering a vertical part and a planar part.

As already indicated, the second active layer 21 is electrically connected to the first upper electrode 121 of the planar stack 10. In the embodiment of [FIG. 1a] and [FIG. 1b], the second active layer 21 is directly electrically connected to the first upper electrode 121. More precisely, it comes into direct contact with the first flank 1211 of this electrode. One surface of the second active layer 21 is thus in contact with this flank 1211. Alternatively, a conductive intermediate layer could however be inserted between the active layer 21 and the first flank 1211.

Thus, the second active layer 21 has a portion disposed between the conductive layer 22 of the second stack 20 and the first upper electrode 121. When the second active layer 21 is, for example, of the OxRAM or CBRAM type, the application of a potential difference between the conductive layer 22 and the first upper electrode 121 during an initial forming operation (first creation of a conductive filament) results in the formation of a conduction channel, in the second active layer 21, at a zone located opposite the first flank 1211, of the first upper electrode 121. The position of the conduction channel is therefore controlled (and, herein, is also remote from the edges—i.e. the ends—of the first active layer), making it possible to reduce variability of the second vertical stack 20.

The second active layer 21 may comprise a planar portion, covering part of the first upper electrode 121. In this way, in order to keep location of the conduction channel at the first flank 1211 of the first upper electrode 121, assembly 1 may then comprise an insulating layer 141, 142. This is for example a layer of dielectric material, such as silicon nitride, especially to form a hard mask. At least a portion 141 of the insulating layer is disposed between said planar portion of the second active layer 21 and the first upper electrode 121, to insulate them electrically from each other. The insulating layer 14 may also extend continuously on the two upper electrodes 121, 122 of the first planar stack 10, as in the alternative embodiment represented in [FIG. 3].

The insulating layer 14 is for example delimited by at least one side surface. When the insulating layer 14 is continuous and in one piece, it is then delimited by a single side surface 1411, 1422. The side surface of the insulating layer 14 comprises two parts, opposite to each other, called the ninth flank 1411 and tenth flank 1422 hereinafter, for example located as an extension of the first and second flanks 1211, 1222. When the insulating layer 14 is divided into two distinct portions 141, 142, it is then delimited by two side surfaces, each delimiting a portion 141, 142. The first portion 141 of the insulating layer may be located in vertical alignment with the first upper electrode 121, and may comprise, in addition to the ninth flank 1411, another part of its side surface, referred to here as the eleventh flank 1412. Similarly, the second part 142 may be delimited, in addition to the tenth flank 1422, by another flank called the twelfth flank 1421. The eleventh and twelfth flanks 1412, 1421 are for example located respectively as an extension of the seventh and eighth flanks 1212, 1221, of the first and second upper electrodes 121, 122.

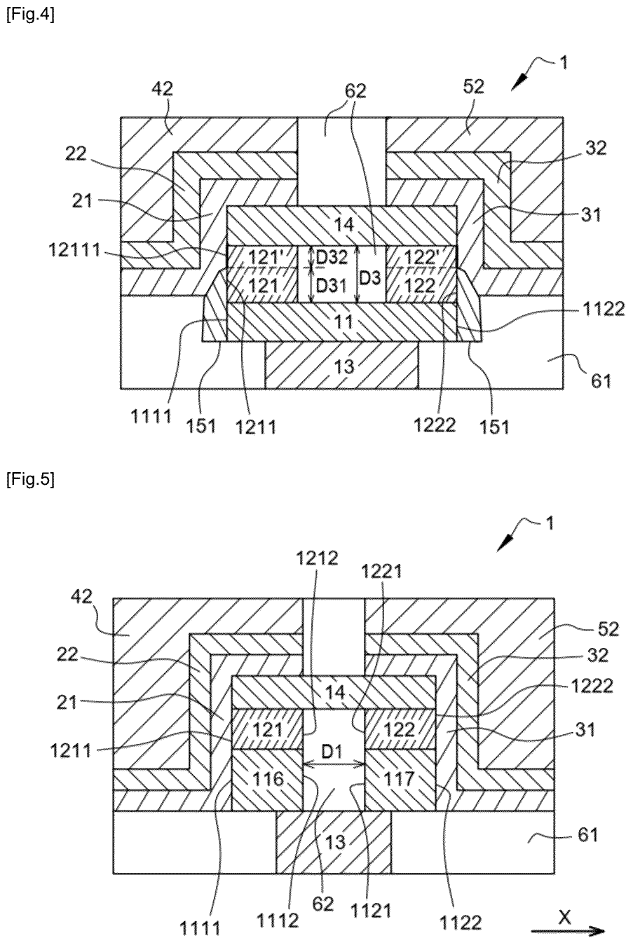

FIG. 4 schematically represents the second embodiment of the memories and selector assembly 1. Unlike the embodiment of [FIG. 1a], [FIG. 1b] and [FIG. 3], the second active layer 21 of the second stack 20 is not in contact with the entire first flank 1211 of the first upper electrode 121.

Indeed, in this second embodiment, the assembly 1 further comprises an electrically insulating spacer 151 which extends against a part of the side surface 1211, 1222 of the first upper electrode 121, and against the side surface 1111, 1122 of the first active layer 11. This spacer 151 especially extends against the third flank 1111 of the first active layer 11 and against a part of the first flank 1211 of the first electrode 121. It makes it possible to reduce surface area of the second active layer 21 in contact with the first flank 1211, for adjusting electrical properties of the non-volatile memory established in this layer. Indeed, reducing thickness D3 of the first upper electrode 121 may present a limit, especially in technological terms. Due to the presence of this spacer 151, only an upper strip 12111 of the side surface of the first electrode 121, especially of the first flank 1211, is in contact with the second active layer 21. Furthermore, the spacer 151 protects the flank 1111 of the first active layer, especially from possible contamination, for example during the steps of manufacturing the assembly, such as the operations of forming the second and third stacks 20, 30.

The first upper electrode 121 can have an additional conductive layer 121′ thereabove, as a vertical extension of the upper electrode 121 (and its first flank 1211). In this way, the first flank 1211 has a total thickness D3 equal to the initial thickness D31 of the first electrode 121 plus an additional thickness D32 of the additional conductive layer 121′. The upper strip 12111 of the first flank 1211 left exposed by the spacer 151 may thus be equal to the additional thickness D32, or even less.

A part of the spacer 151, or possibly another similar spacer, may extend partially between, on the one hand, the first stack and, on the other hand, the third active layer 31. It may especially extend on the second flank 1222 and the fourth side 1122, only partially covering the second flank 1222, in order to expose an upper strip of the second upper electrode, against which the third active layer 31 is in contact.

FIG. 5 schematically represents, in a cross-section view, the third embodiment of assembly 1. Unlike the embodiments in [FIG. 1a], [FIG. 1b] and [FIG. 4], the first active layer 11 is divided into two parts 116, 117. It comprises a first part 116, and a second part 117 separate from the first part 116. The first part 116 is electrically connected between the first upper electrode 121 and the lower electrode 13. The first part 116 of the first active layer 11 extends, for example, in vertical alignment with the first upper electrode 121. It also partly extends on the lower electrode 13 in order to establish electrical contact. The second part 117 of the active layer 11 also extends in vertical alignment with the second upper electrode 122 as an extension of the same. In the same way as the first part 116, the second part 117 partly extends on the lower electrode 13, in order to establish electrical contact.

The first and second parts 116, 117 are advantageously separated by the first distance D1. The physical separation between the two parts 116, 117 makes it possible to electrically insulate the conduction channels that can be established between each upper electrode 121, 122 and the lower electrode 13. In this way, selectors can be operated independently of each other, even when the distance D1 between the two parts 116, 117 is less than 60 nm, or even less than 40 nm. As a reminder, when the first active layer comprises an ovonic material, the conduction channels can have a lateral dispersion of up to 40 nm or even 60 nm. The first and second parts 116, 177 may be in contact with each other, but separated from each other by an insulating barrier, such as a dielectric layer.

The subdivision of the first active layer 11 into two parts (116 and 117) results here from an etching of the whole, of a block, of an initial stack comprising an initial active layer, in one piece, and, on top of this, an upper electrode layer, in one piece (said etching separating this electrode layer to obtain the first and second upper electrodes 121, 122).

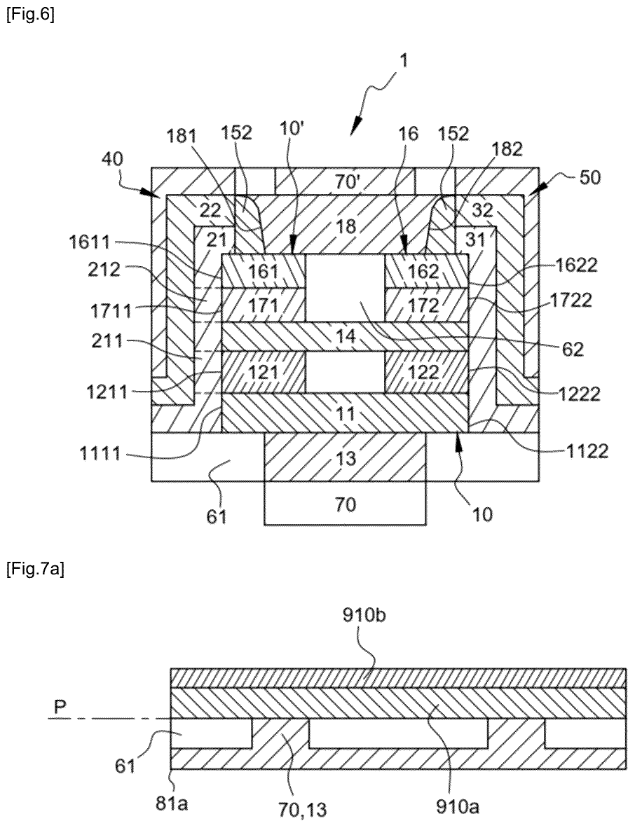

FIG. 6 schematically represents the fourth embodiment of the assembly 1. Unlike the embodiments in the preceding figures, the assembly 1 here comprises a fourth planar selective stack 10′. The first planar stack 10 and the fourth planar stack 10′ are oriented top-to-tail. The assembly also comprises an insulating layer 14 extending between the first and fourth planar stacks 10 and 10′, so as to electrically insulate them from each other.

The fourth selective stack 10′ comprises a fourth active layer 16, a third electrode 171 and a fourth electrode 172. The fourth active layer 16 is also a selective layer. In this example, the fourth active layer 16 is divided into a first part 161 and a second part 162.

The first and second upper electrodes 121, 122 are separated from the third and fourth electrodes 171, 172 by the insulating layer 14. The fourth active layer 16, here its first and second parts 161, 162, extend on, against and above the third and fourth electrodes 171, 172. The third and fourth electrodes 171, 172 are advantageously distinct and separated by an insulator 62, such as a dielectric material. They have no direct electrical contact with each other and are thus electrically insulated from each other.

The first planar stack 10 comprises a lower electrode 13, the first active layer 11 being connected to the lower electrode 13. The fourth planar stack 10′ may also comprise a fifth electrode 18, extending on and above the fourth active layer 16. The fourth active layer 16 is thus electrically connected between the third and fourth electrodes 171, 172 on the one hand, and the fifth electrode 18 on the other hand. The fifth electrode 18 can also be electrically connected to a via, called the upper via 70′, located above the fourth planar stack 10′. The upper via 70′ is disposed between the first and second electrical contacts 40, 50, from a lateral point of view.

The third electrode 171 is also delimited by a side surface comprising at least one vertically oriented flank 1711, referred to as the first additional flank. The first additional flank 1711 is parallel to the first flank 1211 of the first upper electrode 121. The first additional flank 1711 is preferably aligned with the first flank 1211 of the first upper electrode 121, located as an extension thereof. In practice, the overall stack formed by the first planar stack 10, the insulating layer 14 and the fourth planar stack 10′ which covers it, can be laterally delimited during a same overall etching operation, yielding a same overall flank which extends on the entire height of this overall stack (and this on each side, or on each side face of this overall stack).

The second active layer 21 of the second vertical stack 20 vertically extends on an entire part of the height of this overall stack (here, over the entire height of this overall stack, and even more). It extends not only opposite the first flank 1211, the first upper electrode 121, but also opposite the first additional flank 1711, the third electrode 171, in parallel to these flanks 1211, 1711. In this way, the second active layer 21 of the second vertical stack 20 can comprise two distinct conduction channels 211, 212 (one, 211, located in front of the first flank 1211, and the other, 211, located in front of the first additional flank 1711), addressable independently of each other, each enabling a distinct piece of information to be encoded. The single active layer 21 thus makes it possible to form two distinct “memories”.

Like the second active layer 21, the third active layer 31 vertically extends on a part of the height of the overall stack in question (here, over the entire height of this overall stack, and even more). It extends not only opposite a second flank 1222 partly delimiting the second upper electrode 122, but also opposite a second additional flank 1722 of the fourth electrode 172, in parallel to these flanks 1222, 1722.

The fourth active layer 16 is divided into a first part 161 and a second part 162. Said first part 161 extends on the third electrode 171, for example as an extension of the same. Said second part 162 extends, in the same way, on the fourth electrode 172.

The fifth electrode 18 is insulated from each vertical stack 20, 30. It is, for example, insulated by means of additional insulating spacers 152 extending on either side of the fifth electrode 18. The fifth electrode 18 can thus have a smaller width than the lateral extension of the fourth active layer 16 (as for the lower electrode 13 and the first active layer 11). Advantageously, the fifth electrode 18 has a width such that it has at least one part facing each of the third and fourth electrodes 171, 173.

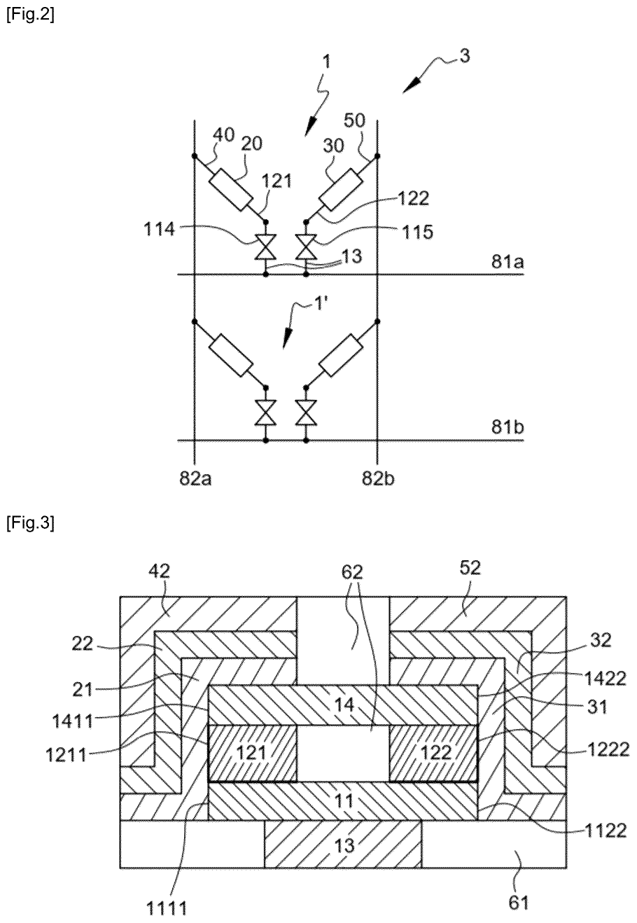

FIG. 2 represents an equivalent electrical diagram of the assembly 1 as described with reference to [FIG. 1a], [FIG. 1b], [FIG. 3], [FIG. 4] and [FIG. 5]. FIG. 2] more broadly represents two assemblies 1, 1′ as described above, belonging to an array 3 of resistive memories. The assemblies 1 and 1′ are preferably identical, connected between two addressing rows 81a, 81b and two addressing columns 82a, 82b. The assembly 1 as described previously is especially connected between a row 81a and two columns 82a, 82b.

The electrical diagram of assembly 1 comprises two circuits connected to a common row 81a. A first circuit comprises the first portion 114 of the first active layer 11, connected in series with the second vertical stack 20. Both are connected between the lower electrode 13 and the first electrical contact 40. The lower electrode 13 is for example connected to the address row 81a and the first electrical contact is connected to a first addressing column 82a. A second circuit comprises the second portion 115 of the first active layer 11, connected in series with the third stack 30, both being connected between the lower electrode 13 and the second electrical contact 50. The second electrical connector is connected to a second addressing column 82b.

[Table 1] below shows a voltage bias diagram for the addressing rows and columns 81a-b, 82a-b for programming a low-resistive state (SET), or erase (writing a high-resistive state, or RESET) operations in each of the first and second memory stacks 20, 30. This is a ‘V/2’ type bias diagram. There are other bias schemes. According to the “V/2” bias scheme, the value of the voltage U applied is chosen so that:
U is greater than the programming voltage of a 1S1R circuit; and
U/2 is less than the threshold voltage of the first active layer 11.

TABLE 1

| Operation | Stack | 81a | 81b | 82a | 82b |
|---|---|---|---|---|---|
| Programming | 20 | 0 | U/2 | U | U/2 |
| | 30 | | | U/2 | U |
| Erase | 20 | U | | 0 | U/2 |
| | 30 | | | U/2 | 0 |

According to one development of the invention, two assemblies 1, such as described for example in [FIG. 1a] and [FIG. 1b], neighbouring to each other, can share a same first selective active layer, overall common to both assemblies. The two assemblies thus form an overall assembly comprising a first overall active layer, four upper electrodes and four memory stacks. The first overall active layer extends, for example, in a single piece, from a first assembly (i.e. a sub-assembly of the overall assembly) to a second assembly. The four upper electrodes extend on the first overall layer and each connect a memory stack to a conduction region of the overall selective layer, i.e. to a selector. The first overall active layer thus makes it possible to form up to four distinct selectors. The overall assembly according to this development therefore comprises four 1S1R type selector/memory assemblies in parallel, independently addressable and enabling four distinct pieces of information to be stored in a non-volatile manner. In other words, the overall assembly is of type nSnR where n is at least equal to four (more generally, at least equal to two).

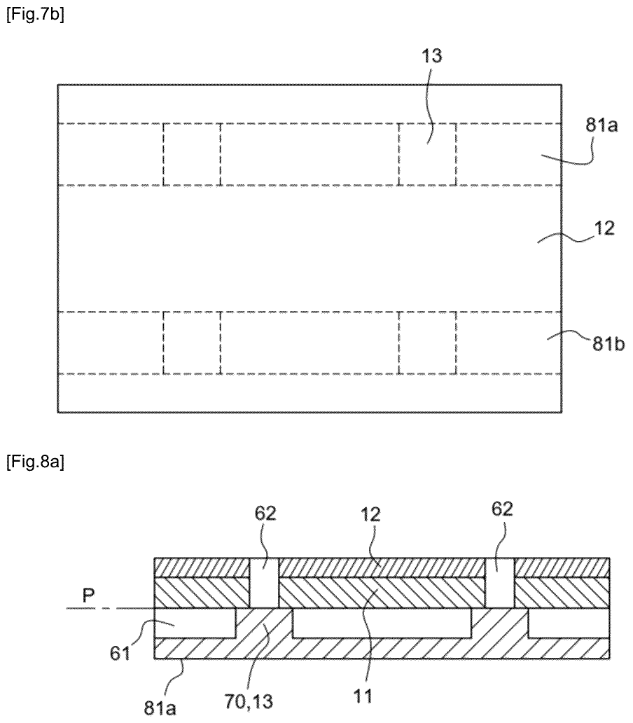

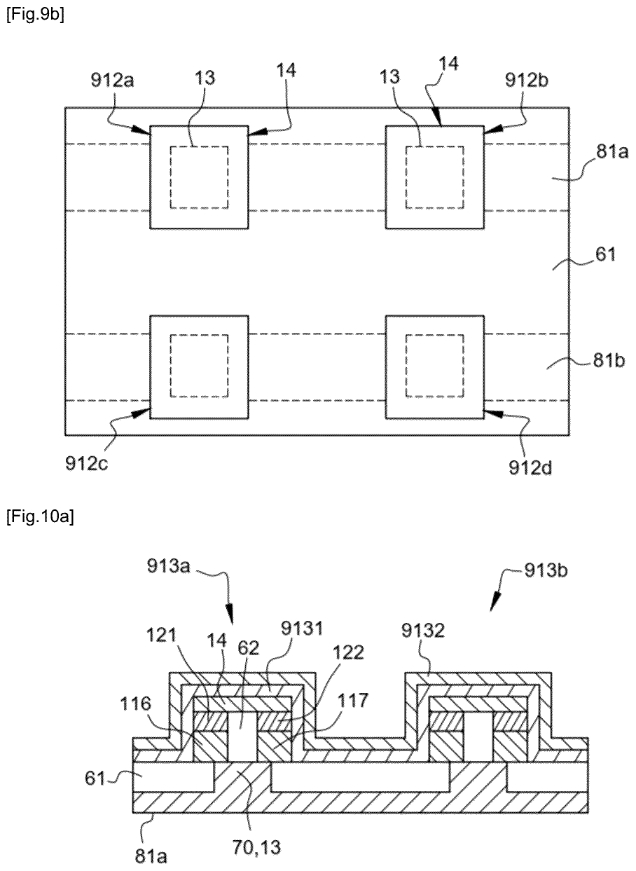

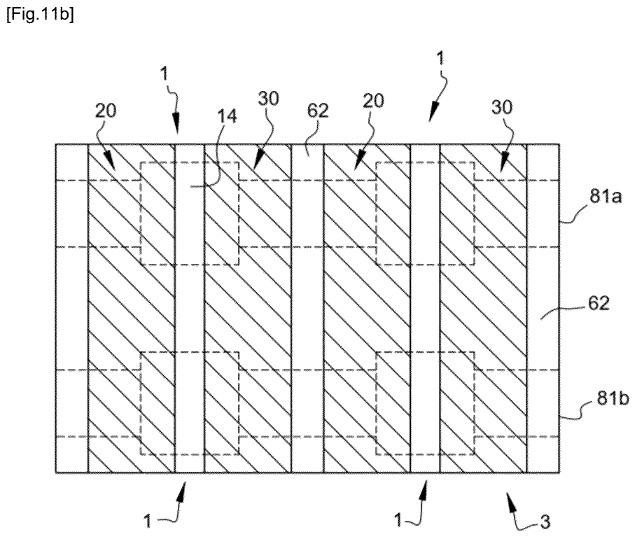

The invention also relates to a method for manufacturing an assembly 1 of memories and selectors as described previously. A mode of implementation of said method is described with reference to [FIG. 7a] to [FIG. 11b].

[FIG. 9a] and [FIG. 9b] represent four first intermediate stacks 912a, 912b, 912c, 912d. The first four intermediate stacks can be made simultaneously, with a view to manufacturing an array 3 of resistive memories. The description below refers to a single first intermediate stack 912a. However, it may be transposed to neighbouring first intermediate stacks 912b, 912c, 912d.

The first intermediate stack 912a comprises, for example from the surface of an addressing row 81a, a lower via 70 and a first planar stack 10 comprising a lower electrode 13, a first active layer 11, a first upper electrode 121 and a second upper electrode 122, each extending on the first active layer 11. The first and second electrodes 121, 122 have an insulating layer 14 thereabove. The first active layer 11 is a selective layer. It is divided into two parts 116, 117 separate from each other. The first intermediate stack 912a thus makes it possible to eventually obtain an assembly 1 according to the embodiment of [FIG. 5].

To obtain said first intermediate stack 912a, the manufacturing method initially comprises a step of forming the first planar stack 10. This step may comprise a sub-step of forming the lower electrode 13, extending for example as an extension of the lower via 70. The lower via 70 and the lower electrode 13 are not differentiated in [FIG. 7a] to [FIG. 7b] so as not to overload the figures. The lower electrode 13 can be made from a TiN alloy. A dielectric layer 62 buries the addressing row 81a and levels the lower electrode 13.

Each addressing row 81a, 81b and each lower via 70 can be made by the implementation of a damascene method. This involves, for example, depositing a dielectric material, etching cavities for forming the addressing rows 81a, 81b or the lower vias 70 and filling said cavities with a liner, for example of titanium nitride, and a conductive material, for example tungsten, followed by chemical mechanical polishing (or CMP). The addressing rows 81a, 81b are buried in the dielectric layer 61. Each lower via 70 passes through the dielectric layer 61.

Each lower electrode 13 is made as an extension of each lower via. Said dielectric layer 61 and each lower electrode 13 are levelled, for example by means of planarisation.

The formation step further comprises a sub-step of forming a first layer 910a, extending in parallel to the plane P, as illustrated in [FIG. 7a] and [FIG. 7b]. The plane P corresponds, for example, to the surface of the lower electrode 13 and of the dielectric layer 61 on which the first layer 910a rests. The first layer 910a is to form the first active layer 11. It is formed, for example, from an ovonic alloy such as Ge—Se—Sb—N. In this way, the first planar stack 10 will provide selector function.

The step of forming the first stack 10 also comprises a sub-step of forming a second layer 910b, for forming the first and second upper electrodes 121, 122. The second layer 910b extends in parallel to the plane P, and rests on the first layer 910a. The second layer 910b is formed from a conductive alloy, for example TiN.

The formation step also comprises a sub-step of delimiting the first and second layers 910a, 910b so as to form the first active layer 11. The first active layer 11 is thus delimited by third and fourth flanks 1111, 1122.

The delimitation sub-step is also carried out so as to obtain the first upper electrode 121 and the second upper electrode 122. The first upper electrode 121 is thus laterally delimited by at least one first flank 1211 and the second upper electrode 122 is delimited by at least one second flank 1222. In practice, the first active layer 11 and the upper electrodes 121, 122 are laterally delimited during a same etching step.

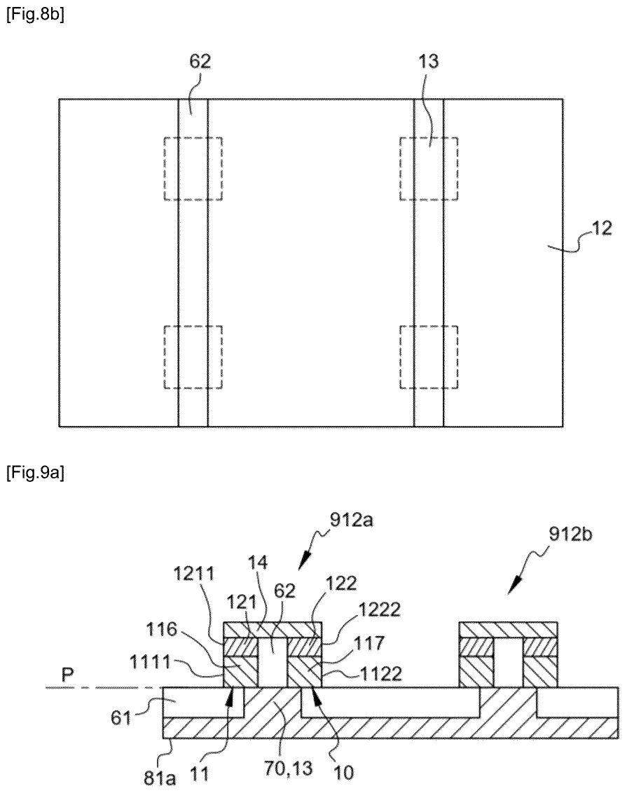

The first and second upper electrodes 121, 122 are also separated during the delimitation sub-step. The delimitation is for example carried out by a first etching, as illustrated by [FIG. 8a] and [FIG. 8b], forming a trench dividing the second layer 910a into two parts, intended to form the upper electrodes 121, 122. A second etching, as illustrated in [FIG. 9a] and [FIG. 9b], then delimits the perimeter of the first planar stack 10.

After the first etching, the trench can be filled with a dielectric material 62. After deposition, the dielectric material 62 is advantageously planarised so as to be flush with the upper surface of the upper electrodes.

The first layer 910a can also be divided into two parts during the first etching. Thus, at the end of the second etching, the first active layer 11 comprises two distinct parts 116, 117, as an extension of the first and second upper electrodes 121, 122.

The first intermediate stack 912a may also comprise an insulating layer 14, extending on the upper electrodes 121, 122. In which case the method may also comprise a sub-step of depositing an insulating layer onto the first and second layers 910a, 910b so that delimiting the same also delimits the insulating layer 14. The insulating layer can be deposited between the first and second etchings described previously. In this way, the insulating layer 14 continuously extends from the first upper electrode 121 to the second upper electrode 122.

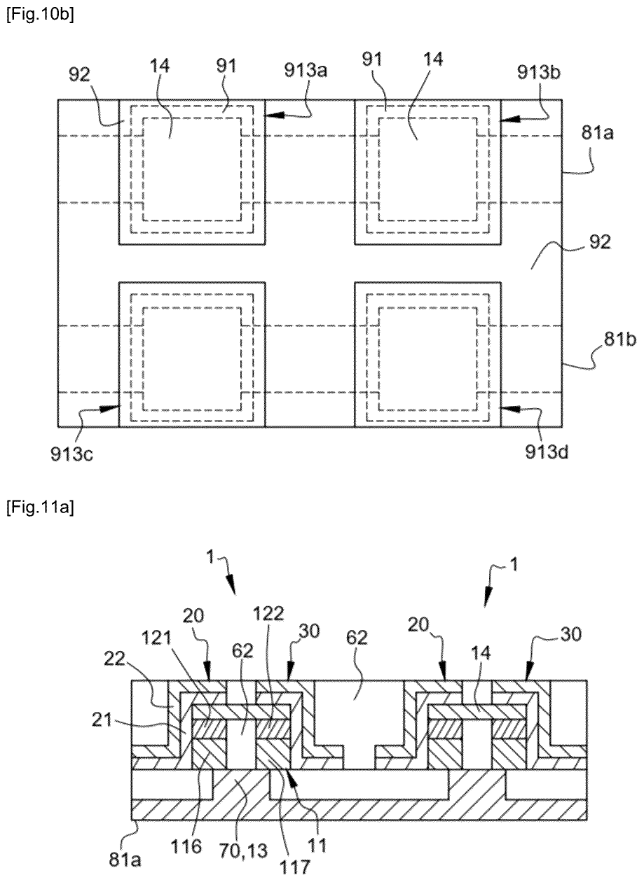

FIG. 10a and [FIG. 10b] represent a second intermediate stack 913a comprising an overall active layer 9131, covering the first planar stack 10 and the surface of the dielectric layer 62 not covered by the planar stacks 10. The overall active layer 9131 is intended to form the second and third active layers 21, 31 of the first and second vertical stacks 20, 30.

The second intermediate stack 913a may also comprise an overall conductive layer 9132 extending on the overall active layer 9131, intended to form the conductive layers 22, 32 of the second and third stacks 20, 30. It may also comprise an additional conductive layer, intended to form at least a part of the first and second electrical contacts 40, 50. Here, the additional conductive layer may be intended, after etching, to form addressing columns of the array.

The formation of the second and third stacks 20, 30 firstly comprises a sub-step of depositing the overall active layer 9131 onto the first planar stack 10 and onto the dielectric layer 61. At least a first part of the overall active layer 9131 extends in parallel to the first and second flanks 1211, 1222 of the upper electrodes 121. It extends especially at least partly opposite the first flank 1211 of the first upper electrode 121 and the second flank 1222 of the second upper electrode 122. Deposition of the overall active layer 9131 is conformally performed, for example so as to have a substantially constant thickness at all points. By substantially constant, it is meant to within at least 20%, for example to within 10% or even 5%, or even better. This conformal deposition is achieved, for example, by ‘ALD’ (Atomic Layer Deposition).

The method may further comprise a sub-step of depositing the conductive layer 9132, for example by conformal deposition, so that it extends on the overall active layer 9131. The method may also comprise a sub-step of depositing the additional conductive layer, for example also by conformal deposition, so that it extends on the conductive layer 9132.

[FIG. 11a] and [FIG. 11b] represent an assembly 1, different from the second intermediate stack 913a of [FIG. 10a] and [FIG. 10b] in that it comprises second and third stacks 20, 30, disposed on either side of the first planar stack 10.

To obtain the second and third memory stacks 20, 30, the method comprises etching the overall active layer 9131 so as to separate it into a second active layer 21 and a third active layer 31. Etching is carried out so that at least a first part of the second active layer 21 extends in parallel to the first flank 1211 of the first upper electrode 121, opposite this first flank 1211, and so that at least a second part of the third active layer 31 extends in parallel to the second flank 1222 of the second upper selector electrode 122, opposite this second flank 1222.

Etching can be stopped before reaching the insulating layer 14. However, according to one development, the overall active layer 9131 and the first planar stack 10 could be etched at one time, thus dividing each layer into two distinct parts. In any case, etching is stopped before reaching the lower electrode 13.

Alternatively, etching step 922 may simultaneously etch conductive layer 9132 in two parts so that they form conductive layers 22, 32 respectively, extending for example over second and third active layers 21, 31 respectively. For the assembly formed to be functional, it is necessary for the etching step to divide at least the layer 9132.

The electrical contacts 42, 52 are formed, for example, at the same time as the etching of the conductive layer 9132. It thus enables the electrical contacts 42, 52 to be electrically separated from each other.

The etching step can also be used to electrically separate neighbouring second intermediate stacks 913b, 913c, 913d by separating the layers 9131, 9132 deposited onto each first planar stack 10.

FIG. 11a and [FIG. 11b] represent assemblies 1 of resistive memories 1 forming an array 3 of resistive memories. Each of the second and third vertical stacks 20, 30 are connected to distinct addressing columns. In order to connect each vertical stack 20, 30, the method may comprise forming addressing columns. For this, the assemblies 1 are buried beneath a complementary dielectric layer 62. The complementary dielectric layer 62 is levelled with each electrical contact by planarisation. The addressing columns are then formed, for example by the implementation of a damascene method.

1. An assembly comprising at least two non-volatile resistive memories electrically disposed in parallel with each other and each being electrically connected in series to a selective layer respectively forming at least two selectors, each dedicated to one of the memories, the assembly including:
a first planar stack, comprising:
a first active layer which extends in parallel to a given horizontal plane, the first active layer being said selective layer; and
a first upper electrode and a second upper electrode which both extend on the first active layer and which are electrically insulated from each other, the first upper electrode being laterally delimited by a side surface, the second upper electrode being laterally delimited by another side surface, an insulating layer extending between a part of the side surface of the first upper electrode and a part of the side surface of the second upper electrode to electrically insulate the first upper electrode from the second upper electrode;
a second stack, which extends obliquely or perpendicularly to said plane, comprising a second active layer, at least a part of the second active layer extending opposite another part of the side surface of the first upper electrode, the second active layer being in electrical contact with the first upper electrode, the second active layer being a non-volatile resistive memory layer;
a third stack, which extends obliquely or perpendicularly to said plane, comprising a third active layer, at least a part of the third active layer extending opposite another part of the side surface of the second upper electrode, the third active layer being in electrical contact with the second upper electrode, the third active layer being a non-volatile resistive memory layer;
the second and third active layers being disjoint, with no direct electrical contact therebetween.

2. The assembly according to claim 1,
comprising a lower electrode, which extends beneath the first active layer, in parallel thereto, and which is in electrical contact with a lower face of the first active layer, wherein
at least a part of the first upper electrode is located in vertical alignment with the lower electrode, superimposed on the lower electrode, in a projection along a direction perpendicular to said plane, and wherein
at least a part of the second upper electrode is located in vertical alignment with the lower electrode, superimposed on the lower electrode, in a projection along a direction perpendicular to said plane.

3. The assembly according to claim 2, wherein at least one of the upper electrodes is only partially superimposed on the lower electrode.

4. The assembly according to claim 2, wherein:
the first and second upper electrodes are separated from each other, along a given horizontal direction, by a given spacing, and wherein
along said direction, the first upper electrode is superimposed on the lower electrode over a distance which is less than said spacing.

5. The assembly according to claim 2, wherein the first active layer laterally extends beyond the lower electrode, protruding on a dielectric layer which surrounds the lower electrode.

6. The assembly according to claim 1, wherein:
the first active layer is laterally delimited by a side surface, and
the assembly further comprises an electrically insulating spacer which extends at least against the side surface of the first active layer, at least partly covering this side surface.

7. The assembly according to claim 6, wherein the spacer also covers, only partly, the side surface of at least one of the first and second upper electrodes.

8. The assembly according to claim 1, wherein the first and second upper electrodes are in direct contact with the first active layer.

9. The assembly according to claim 1, wherein the first planar stack comprises an insulating layer which extends above the first and second upper electrodes.

10. The assembly according to claim 9, comprising a fourth, planar, stack disposed on the insulating layer, the fourth stack comprising:
a fourth active layer which extends in parallel to said plane, the fourth active layer being a selective layer;
a third and a fourth electrode which extend in parallel to said plane, between the fourth active layer and the insulating layer, and which are electrically insulated from each other, the third electrode being laterally delimited by a side surface, the fourth electrode being laterally delimited by another side surface, an insulating layer extending between a part of the side surface of the third electrode and a part of the side surface of the fourth electrode to electrically insulate the third electrode from the fourth electrode;
wherein the second active layer extends beyond the side surface of the first upper electrode, extending along a part of the side surface of the third electrode,
and wherein the third active layer extends beyond the side surface of the second upper electrode by extending along a part of the side surface of the fourth electrode.

11. The assembly according to claim 10, wherein the fourth stack comprises:
a fifth electrode, which extends above the fourth active layer, in electrical contact with the fourth active layer, and
an electrically insulating third spacer which covers a side surface of the fifth electrode.

12. The assembly according to claim 1, wherein the first active layer, common to the second and third stacks, is continuous, in one piece.

13. The assembly according to claim 1, wherein the first active layer is divided into a first part and a second part, which are disjoint, the first part of the active layer extending beneath the first upper electrode, the second part of the active layer extending beneath the second upper electrode.

14. A resistive memory array comprising a plurality of assemblies according to claim 1, wherein, for each assembly:
the first planar stack of the assembly is electrically connected to an addressing row of the array,
the second and third vertical stacks of the assembly are electrically connected to two addressing columns of the array respectively, the two addressing columns being distinct.

15. A method for manufacturing an assembly comprising at least two non-volatile resistive memories electrically disposed in parallel with each other and each electrically connected in series to a selective layer forming at least two selectors respectively, each dedicated to one of the memories, the method comprising:
forming a first planar stack comprising:
depositing a first active layer extending in parallel to a given horizontal plane, the first active layer being said selective layer; and
depositing a first upper electrode and a second upper electrode which both extend on the first active layer and which are electrically insulated from each other, the first upper electrode being laterally delimited by a side surface, the second upper electrode being laterally delimited by another side surface, an insulating layer extending between a part of the side surface of the first upper electrode and a part of the side surface of the second upper electrode to electrically insulate the first upper electrode from the second upper electrode;
forming a second stack, which extends obliquely or perpendicularly to said plane, comprising a second active layer, at least a part of the second active layer extending opposite another part of the side surface of the first upper electrode, the second active layer being in electrical contact with the first upper electrode, the second active layer being a non-volatile resistive memory layer;
forming a third stack, which extends obliquely or perpendicularly to said plane, comprising a third active layer, at least a part of the third active layer extending opposite another part of the side surface of the second upper electrode, the third active layer being in electrical contact with the second upper electrode, the third active layer being another non-volatile resistive memory layer.

16. The method according to claim 15, wherein of forming the second and third stacks are performed by carrying out:
conformally depositing an overall active layer, a first part of the overall active layer extending opposite the side surface of the first upper electrode, the first part of the overall active layer being in electrical contact with the first upper electrode, a second part of the overall active layer extending opposite the side surface of the second upper electrode, the second part of the overall active layer being in electrical contact with the second upper electrode;
separating the overall active layer into at least said second active layer and said one third active layer, which are disjoint.
